(19) United States
(12) Patent Application Publication
(10) Pub. No.: US 2013/0106524 A1
(43) Pub. Date: May 2, 2013

(54) SYSTEM AND METHOD FOR EXAMINING LEAKAGE IMPACTS

(71) Applicants: Ilyas Elkin, Sunnyvale, CA (US); Wojciech Jakub Poppe, San Jose, CA (US)

(72) Inventors: Ilyas Elkin, Sunnyvale, CA (US); Wojciech Jakub Poppe, San Jose, CA (US)

(73) Assignee: NVIDIA CORPORATION, Santa Clara, CA (US)

(21) Appl. No.: 13/287,044

(22) Filed: Nov. 1, 2011

(51) Int. Cl. H03K 3/03; H03K 3/356

(52) U.S. Cl. 331/57; 327/208

(57) ABSTRACT

Leakage inversion systems and methods are described. A leakage inverter can be configured to transition a signal, wherein a leakage characteristic impacts a transition of the signal. The leakage inverter can be included in an oscillating ring path that outputs an indication of the impacts the leakage characteristic has on a transition of a signal. A leakage inverter can include a leakage transistor coupled in series between a pull up transistor and a pull down transistor, wherein leakage in the leakage transistor impacts at least one transition of the signal. A pull down transition delay can be asymmetric (e.g., fast/slow, short/long, etc.) with respect to a pull up transition delay. Asymmetry can be associated with an effect of the leakage current on a transition of the signal. Results can be utilized in a variety of different analysis (e.g., analyze manufacturing process compliance and defects, leakage current power consumption, etc.).

### FIELD OF THE INVENTION

The present invention relates to examining semi-conductor chip component operations. In particular, the present invention relates to a system and method for examining impacts associated with leakage current.

### BACKGROUND OF THE INVENTION

Electronic systems and circuits have made a significant contribution towards the advancement of modern society and are utilized in a number of applications to achieve advantageous results. Numerous electronic technologies such as digital computers, calculators, audio devices, video equipment, and telephone systems have facilitated increased productivity and reduced costs in analyzing and communicating data in most areas of business, science, education and entertainment. The manner in which the electronic devices perform operations can have a significant impact on the performance and end results. However, traditional attempts at accurately analyzing impacts associated with different aspects of how a device operates are often limited and can be very complex and complicated.

A variety of things can impact operations of a device (e.g., manufacturing parameters, environment, temperature, etc.). Electronic devices often include components that have leakage currents. Leakage currents can have a variety of impacts on the performance and operations of a device (e.g., wasted power consumption, timing delays, etc.). Adequately isolating and examining the impacts of leakage currents can be very difficult.

### SUMMARY

Leakage inversion systems and methods are described. In one embodiment, at least one leakage inverter is configured to transition a signal, wherein a leakage characteristic impacts a transition of the signal. The impact can include a longer transition delay. In one exemplary implementation, the at least one leakage inverter is coupled as part of an oscillating ring path. The oscillating ring path can include an output that outputs an indication of the impacts the leakage characteristic has on a transition of a signal. A leakage inverter can include a pull up transistor configurable to pull up a signal; a pull down transistor configurable to pull down the signal; and a leakage transistor coupled in series between the pull up transistor and the pull down transistor, wherein leakage in the leakage transistor impacts at least one transition of the signal. A signal transition delay associated with the pull down operation can be asymmetric with respect to a signal transition delay associated with the pull up operation and the asymmetry (e.g., fast/slow, short/long, etc.) is associated with an effect of the leakage current on the at least one transition of the signal. In one embodiment, the output of a leakage inverter can be utilized in a variety of different analysis (e.g., analyze manufacturing process compliance and defects, leakage current power consumption, etc.).

### DESCRIPTION OF THE DRAWINGS

The accompanying drawings, which are incorporated in and form a part of this specification, illustrate embodiments of the invention by way of example and not by way of limitation. The drawings referred to in this specification should be understood as not being drawn to scale except if specifically noted.

FIG. 1 is a block diagram of an exemplary leakage inverter in accordance with one embodiment of the present invention.

FIG. 2 is a block diagram of exemplary leakage inverters with MOS components in accordance with some embodiments of the present invention.

FIG. 3 is a block diagram of an exemplary ring oscillator in accordance with one embodiment of the present invention.

FIG. 4 is a block diagram of an exemplary leakage inversion graph in accordance with one embodiment of the present invention.

FIG. 5 is a block diagram of another exemplary ring oscillator in accordance with one embodiment of the present invention.

FIG. 6 is a block diagram of an exemplary leakage inverter input control configuration in accordance with one embodiment of the present invention.

FIG. 7 is a block diagram of an exemplary leakage inverter output control configuration in accordance with one embodiment of the present invention.

FIG. 8 is a block diagram of an exemplary leakage inverter and control ring configuration in accordance with one embodiment of the present invention.

FIG. 9 is a block diagram of an exemplary analysis system in accordance with one embodiment of the present invention.

FIG. 10 is a block diagram of another exemplary analysis system in accordance with one embodiment of the present invention.

FIG. 11 is a flow chart of an exemplary analysis method in accordance with one embodiment of the present invention.

FIG. 12 is a flow chart of an exemplary leakage inversion process in accordance with one embodiment of the present invention.

FIG. 13 is a flow chart of an exemplary analysis process in accordance with one embodiment of the present invention.

FIG. 14 is a flow chart of an exemplary leakage inverter formation process in accordance with one embodiment of the present invention.

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well known methods, procedures, components, and circuits have not been described in detail as not to unnecessarily obscure aspects of the present invention.

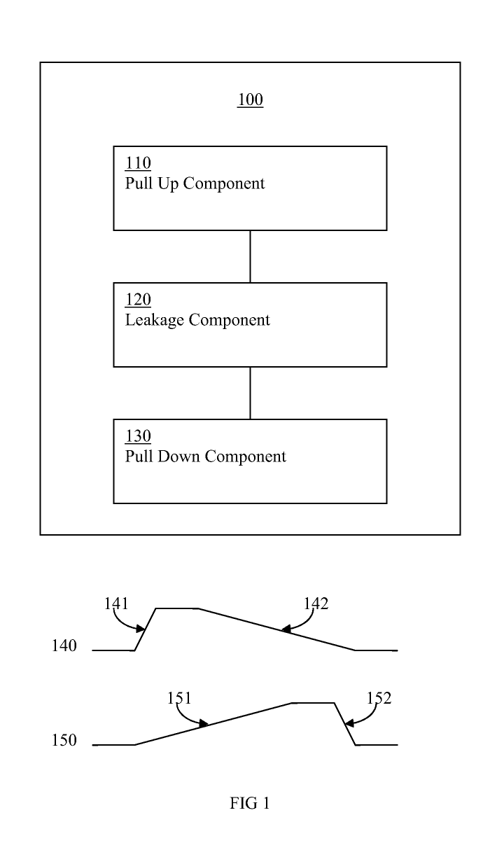

FIG. 1 is a block diagram of an exemplary leakage inverter 100 in accordance with one embodiment of the present invention. Leakage inverter 100 comprises a pull up component 110, leakage component 120 and pull down component 130. In one exemplary implementation, leakage component 120 is coupled in series between the pull up component 110 and the pull down component 120. The components of leakage inverter 100 cooperatively operate to pull up and pull down a signal. In one embodiment, pull up component 110 is configurable to perform a pull up operation to pull up a signal, pull down component 120 is configurable to perform a pull down operation to pull down the signal; and a leakage in leakage component 130 impacts at least one transition of the signal.

In one embodiment, a transition delay associated with the pull down operation is asymmetric with respect to transition delay associated with the pull up operation and the asymmetry is associated with an effect of the leakage current on the at least one transition of the signal. In one exemplary implementation, the at least one transition of the signal is represented by graph 140 with a relatively fast rising transition delay 141 and a relatively slow transition delay 142. In one exemplary implementation, the at least one transition of the signal is represented by graph 150 with a relatively slow rising transition delay 151 and a relatively fast transition delay 152. It is appreciated that pull up component 110, leakage component 120 and pull down component 130 can include a variety of components. In one embodiment, the leakage component includes a transistor in the off state that allows leakage current to flow.

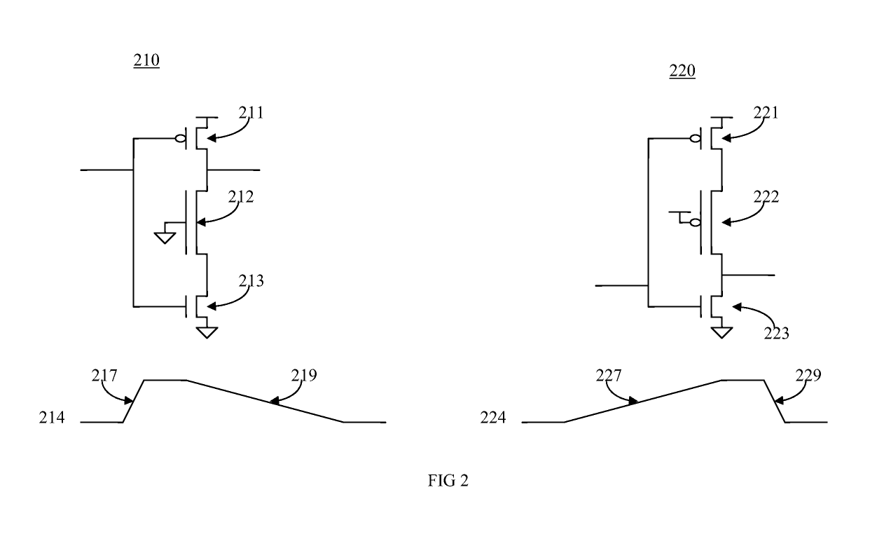

FIG. 2 is a block diagram of exemplary leakage inverters with MOS components in accordance with some embodiments of the present invention. It is appreciated there are a variety of other leakage inverter configurations. Leakage inverter 210 includes a NMOS leakage transistor and leakage inverter 220 includes a PMOS leakage transistor.

Leakage inverter 210 includes pull up component PMOS transistor 211, leakage component NMOS leakage transistor 212 and pull down component NMOS transistor 213. In one exemplary implementation, the incoming signal is low and pull down component NMOS transistor 213 turns off, pull up component PMOS transistor 211 turns on to perform a pull up operation and leakage component NMOS transistor 212 does not impact an output signal transition to a pulled up value. In one exemplary implementation, the incoming signal is high and pull up component PMOS transistor 211 turns off, pull down component NMOS transistor 213 turns on to perform a pull down operation but leakage component NMOS transistor 212 impacts the output signal transition. As leakage component NMOS transistor 212 is off the pull down transition delay corresponds to a delay for leakage current and corresponding pull down value to “propagate” through the leakage component NMOS transistor 212. In one embodiment, the operations of leakage inverter 210 are represented by graph 214 with a relatively fast rising transition delay 217 and a relatively slow falling transition delay 219.

Leakage inverter 220 includes pull up component PMOS transistor 221, leakage component PMOS leakage transistor 222 and pull down component NMOS transistor 223. In one exemplary implementation, the incoming signal is high and pull up component PMOS transistor 221 turns off, pull down component NMOS transistor 223 turns on to perform a pull down operation and leakage component PMOS transistor 222 does not impact an output signal transition to a pulled down value. In one exemplary implementation, the incoming signal is low and pull down component NMOS transistor 223 turns off, pull up component PMOS transistor 221 turns on to perform a pull up operation but leakage component PMOS transistor 222 impacts the output signal transition. As leakage component PMOS transistor 222 is off the pull down transition delay corresponds to a delay for leakage current and corresponding pull up value to “propagate” through the leakage component PMOS transistor 222. In one embodiment, the operations of leakage inverter 220 are represented by graph 224 with a relatively slow rising transition delay 227 and a relatively fast falling transition delay 229.

It is appreciated that a leakage inverter can be included in a variety of component configurations. In one embodiment, the leakage inverter can be included in a ring configuration. In one exemplary implementation, the ring oscillator includes at least one leakage inverter configured to transition a signal, wherein a leakage current impacts a transition of the signal and the at least one leakage inverter is coupled as part of a ring path. The at least one leakage inverter can include a leakage component coupled in series between a pull up component and a pull down component, wherein leakage in the leakage component impacts at least one transition. The at least one leakage inverter can have a rising transition delay and a falling transition delay that are asymmetric. The ring oscillator can include an output including an indication of a transition delay in the signal and can include a control component coupled to the ring path to control a state of the signal. It is appreciated the ring oscillator can include a plurality of leakage inverters. In one exemplary implementation, at least one leakage inverter is coupled in series to another leakage inverter in the ring path.

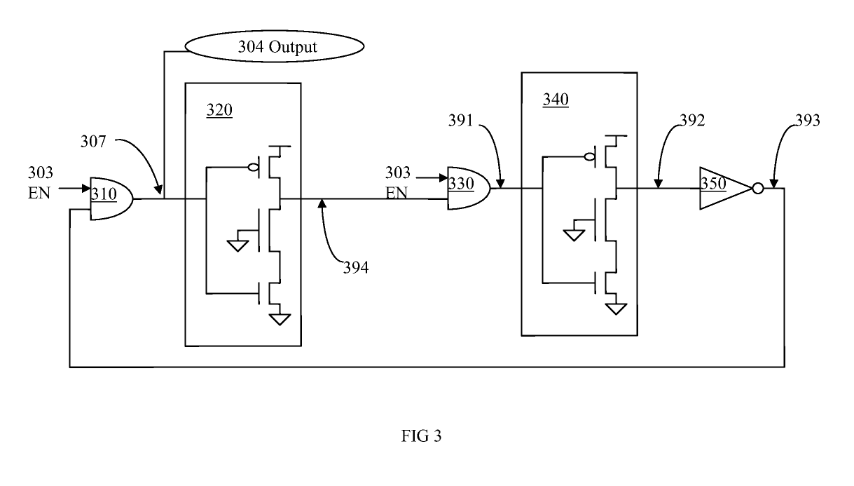

FIG. 3 is a block diagram of exemplary ring oscillator 300 in accordance with one embodiment of the present invention. Ring oscillator 300 includes leakage inverters 320 and 340, AND logic components 310 and 330, and driven inverter 350. The components are coupled in series in a ring path. Leakage inverters 320 and 340 include NMOS leakage transistors.

The components of ring oscillator 300 cooperatively operate to oscillate a signal. In one embodiment, oscillations include inversions of a signal state. Leakage inverters 320 and 340 oscillate or invert a signal state wherein at least one inversion transition is impacted by a leakage characteristic of a leakage inverter. In one exemplary implementation, the oscillation rising transitions and falling transitions have asymmetric transition delays. In one embodiment, leakage inverters 320 are NMOS leakage inverters similar to leakage inverter 210. The AND logic components 310 and 330 can control a signal and drive the signal to a value. An enable signal 303 can be used to “enable” AND control logic components 310 and 330. While the present embodiment of oscillation ring 300 is shown with the same enable signal 303 “enabling” AND logic components 310 and 330, it is appreciated that a different respective enable signal can be used to “enable” each of the AND logic components 310 and 330. Driven inverter 350 switches on and off states in response to a drive signal without impacts associated with a leakage transistor. Ring oscillator has a split 307 in the ring path that forwards an output 304. The state of output 304 is similar to the state of an input to leakage inverter 320.

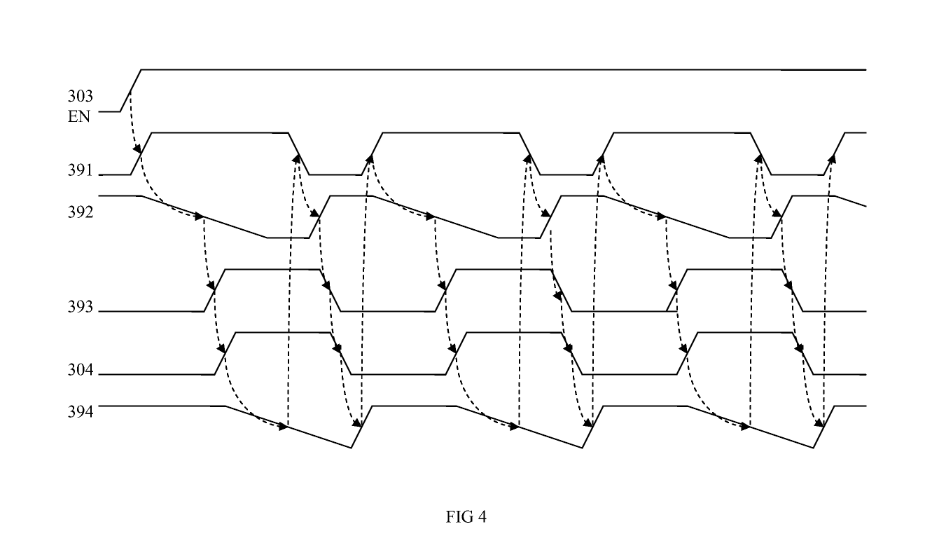

FIG. 4 is a block diagram of exemplary leakage inversion graph 400 in accordance with one embodiment of the present invention. The enable signal 303 is set high to “enable” the flow of information through the AND gates 310 and 320 for an output that mimics the logic value on the other input of the AND gates. In one exemplary implementation, the enabling initiates a transition to a high logic value in a signal at point 391 of the oscillating ring. This high logic value at the input of leakage inverter 340 triggers an inverse transition or falling transition to a low logic value at point 392 of an output signal from leakage inverter 340. As shown in the figure, the delay in completing a falling transition in a signal from the leakage inverter 340 is relatively long compared to rising transitions in the signal at point 392. The output at point 393 of a subsequent driven inverter 350 is inverted. The transitions in output signal 304 mimic transitions at point 393 with a slight time shift due to propagation through AND component 310. The output from leakage inverter 320 at point 394 again has relatively slow or long falling transitions and relatively fast or short rising transitions.

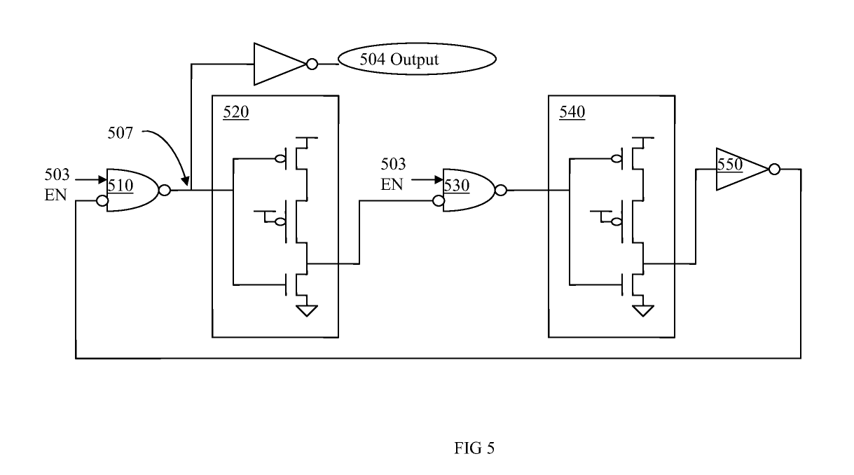

FIG. 5 is a block diagram of exemplary ring oscillator 500 in accordance with one embodiment of the present invention. Ring oscillator 500 includes leakage inverters 520 and 540, control components 510, 530, and 550. The components are coupled in series in a ring path. Leakage inverters 520 and 540 include PMOS leakage transistors.

The components of ring oscillator 500 cooperatively operate to oscillate a signal. In one embodiment, oscillations include inversions of a signal state. Leakage inverters 520 and 540 oscillate or invert a signal state wherein at least one inversion transition is impacted by a leakage characteristic of a leakage inverter. In one exemplary implementation, the oscillations rising transitions and falling transitions have asymmetric transition delays. In one embodiment, leakage inverters 520 and 540 are PMOS leakage inverters similar to leakage inverter 220. The control components 510 and 530 can control a signal and drive the signal to a value. In one embodiment, control component 510 and 530 respectively include a NAND logic component with a first input coupled to an enable and an inverted second input coupled to the ring path. An enable signal 503 can be used to “enable” AND control logic components 510 and 530. It is appreciated that a different respective enable signal can be used to “enable” each of the NAND logic components 510 and 530. Control component 550 includes a driven inverter that switches on and off states in response to a drive signal. The driven inverter switches on and off states in response to a drive signal without impacts associated with a leakage transistor. Ring oscillator has a split 507 in the ring path that forwards an output 504. The state of output 504 is similar to the state of an input to leakage inverter 520.

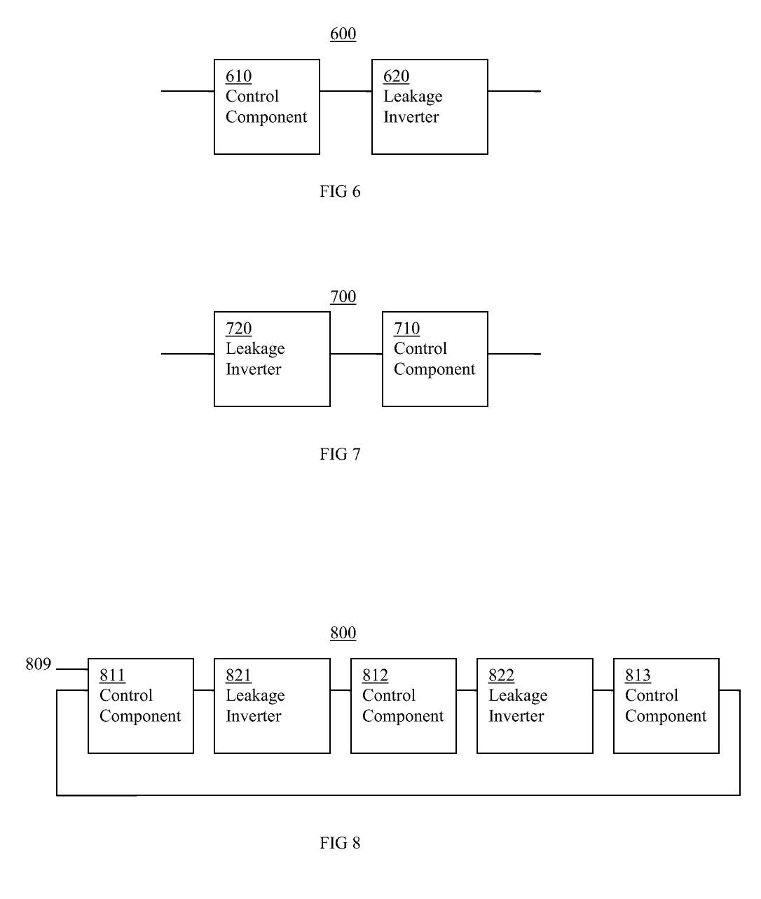

It is appreciated that a variety of controls can be utilized with the leakage inverters. FIG. 6 is a block diagram of an exemplary leakage inverter input control configuration 600 in accordance with one embodiment of the present invention. Leakage inverter input control configuration 600 includes control component 610 and leakage inverter 620. Control component 610 controls the input to leakage inverter 620. It is appreciated that control component 610 can control the input to leakage inverter 620 in a variety of ways. Control component 610 can include a variety of different components (e.g., logic gates, on/off driven inverters, etc.). Control component 610 can control a state (e.g., logical value, high/low voltage, etc.) of an input to leakage inverter 620. Control component 610 can control a timing (e.g., synchronize with other inputs, trigger based upon an enable, etc) of an input to leakage inverter 620.

FIG. 7 is a block diagram of an exemplary leakage inverter output control configuration 700 in accordance with one embodiment of the present invention. Leakage inverter output control configuration 700 includes control component 710 and leakage inverter 720. Control component 710 controls the output from leakage inverter 720. It is appreciated that control component 710 can control the output from leakage inverter 720 in a variety of ways. Control component 710 can control a state (e.g., logical value, high/low voltage, etc.) of an output from leakage inverter 720. Control component 710 can control a timing (e.g., synchronize with other outputs, trigger based upon an enable, etc) of an output from leakage inverter 720.

It is appreciated that at least one leakage inverter and control component can be implemented alone or in combination with other control components and leakage inverters. FIG. 8 is a block diagram of an exemplary leakage inverter and control ring configuration 800 in accordance with one embodiment of the present invention. Control ring configuration 800 includes control components (e.g., 811, 812 and 813) and leakage inverters (e.g., 821 and 822). Control components 811, 812 and 813 can be utilized to implement a variety of different type of controls (e.g., state determination, timing, etc.). It is appreciated that control components 811, 812 and 813 can receive control inputs (e.g., enables, triggers, etc.) that direct the control. In one embodiment, control component 811 receives control input 809. In one exemplary implementation control components 811 and 812 include logic gates (e.g., similar 310, 3130, 510, 530, etc.) and control component 813 includes an on/off driven inverter (e.g., similar to 350, 550, etc.).

It is appreciated there can be a variety of leakage inversion stages whose delay is driven predominantly by leakage current. In one embodiment, the leakage inversion stage can be a leakage starving stage that is not necessarily inverter. In one embodiment, instead of having just one of the stages gated it can have basically both of them gated. In one exemplary implementation both N and P would be gated with a leakage device. There can be a really tiny generalization as a leakage current starved inverter. There can be a drive inverter and a pass gate that is off, like a tri-state inverter that is off essentially.

It is appreciated that outputs from leakage inversion scenarios can be utilized in a variety of different analysis. In one embodiment, the leakage inversion outputs can be utilized in detecting transition delays that are utilized to analyze a variety of concerns. In one exemplary implementation, the leakage inversion outputs can be utilized to analyze manufacturing process compliance and defects.

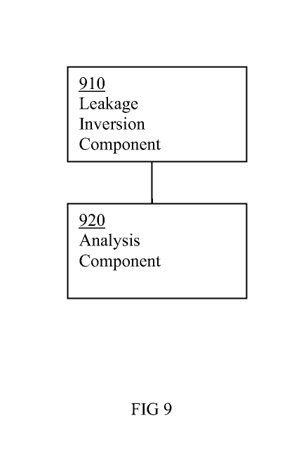

FIG. 9 is a block diagram of exemplary analysis system 900 in accordance with one embodiment of the present invention. Analysis system 900 includes leakage inversion component 910 and analysis component 920. It is appreciated that the leakage inversion component 910 can include a variety of leakage inversion implementations. Leakage inversion component 910 can include at least one leakage inverter (e.g., 100, 210, 220, etc.). Leakage inversion component 910 can include at least one control component (e.g., 310, 510, 610, 710, etc.). It is also appreciated that analysis component 920 can include a variety of implementations. The analysis component 920 can include components on chip with the leakage inversion component, components off chip from the leakage inversion component, combination of components on and off chip. It is also appreciated that the analysis component 920 can perform a variety of different analysis. In one exemplary implementation, the analysis can include transition delays, determination of leakage power consumption, manufacturing process compliance and defects, etc.

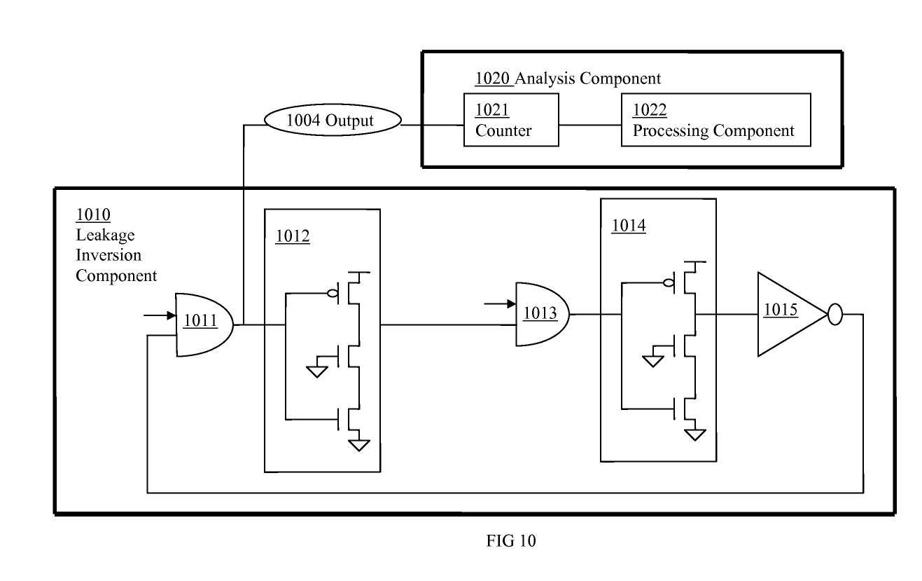

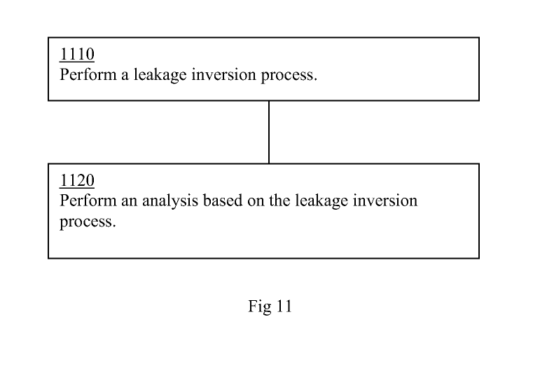

FIG. 10 is a block diagram of exemplary analysis system 1000 in accordance with one embodiment of the present invention. Analysis system 1000 includes leakage inversion component 1010 and analysis component 1020. Leakage inversion component 1010 includes a leakage oscillating ring comprising AND gates 1011 and 1013, leakage inverters 1012 and 1014, and on/off driven inverter 1015 coupled in a ring path. Output 1004 is forwarded from leakage inversion component 1010 to analysis component 1020. Analysis component 1020 includes counter 1021 and processing component 1022.

FIG. 11 is a flow chart of exemplary analysis method 1100 in accordance with one embodiment of the present invention.

In block 1110, a leakage inversion process is performed. In one embodiment, the leakage inversion process includes pull ups and pull downs wherein at least one transition is impacted by leakage characteristics. In one exemplary implementation, the leakage inversion process includes transitions between a logical 1 state to a logical 0 state.

In block 1120, an analysis process is performed based upon the leakage inversion process. It is appreciated that a variety of different analysis can be performed. In one embodiment results from a ring oscillator including a leakage inverter are compared to a spice simulation of the circuit. If the actual physical implementation is running faster then it is an indication the leakage is higher than expected.

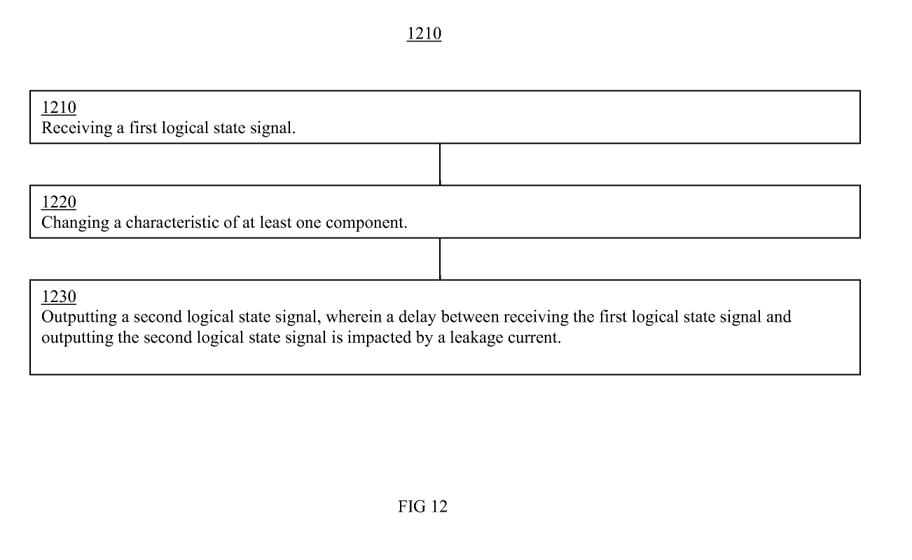

FIG. 12 is a flow chart of exemplary leakage inversion process 1200 in accordance with one embodiment of the present invention. In one embodiment, leakage inversion process 1200 is similar to the leakage inversion process of block 1110.

In block 1210, a signal in a first state is received. The signal can be a first logical state signal (e.g., a characteristic of the signal corresponds to a first logical state, etc.). In one embodiment, the first logic state signal can correspond to a logical 1. In another embodiment, the first logic state signal can correspond to a logical 0. In one exemplary implementation, the first logic state signal can correspond to a pulled up or high voltage signal. In another exemplary implementation, the first logic state signal can correspond to a pulled down or low voltage signal.

In block 1220, a characteristic of at least one component is changed. In one embodiment, the component is a transistor and a characteristic of the at least one transistor is changed. The transistor can be a pull up transistor or a pull down transistor. Changing the characteristic of the transistor can turn the transistor on or off. In one embodiment, a voltage value at a gate of the transistor and a characteristic (e.g., resistance of a channel, etc.) is changed to turn on or off the transistor. In one exemplary implementation, the change in the component inverts the logical value of a signal.

In block 1230, a signal in a second state is output, wherein a delay between receiving the first logical state signal and outputting the second logical state signal is impacted by a leakage current. The signal can be a second logic state signal. In one embodiment, the second logic state is the opposite or inverse of the first logic state. In one exemplary implementation, the first logical state is a logical 1 and the second logical state is a logical 0. In another exemplary implementation, the first logical state is a logical 0 and the second logical state is a logical 1. In one embodiment, a leakage current increases or makes the delay longer than would otherwise take if the leakage current was not impacting the transition.

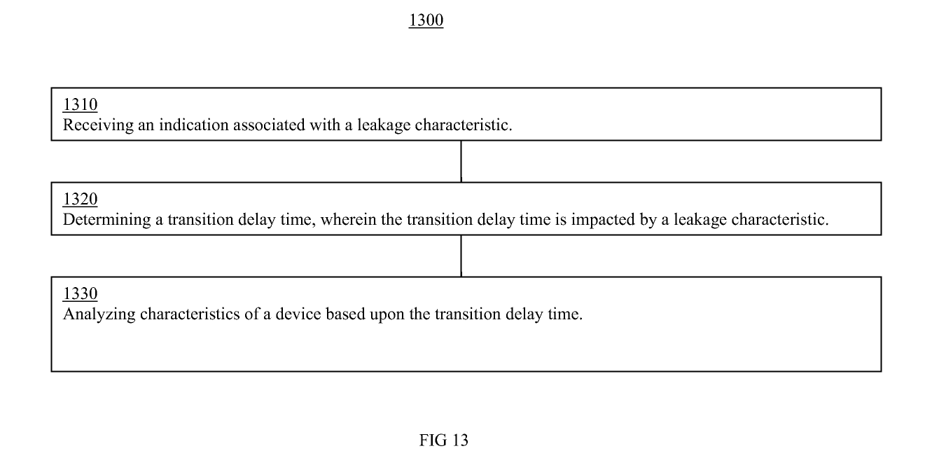

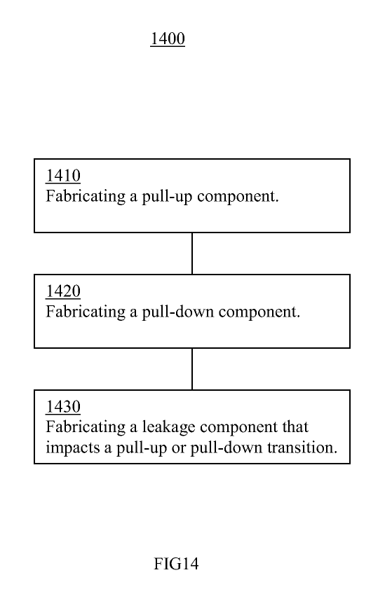

FIG. 13 is a flow chart of exemplary analysis process 1300 in accordance with one embodiment of the present invention. In one embodiment, analysis process 1300 is similar to the analysis process of block 1120.

In block 1310, an indication associated with a leakage characteristic is received. In one embodiment, the indication includes transitions in a signal in which at least one transition delay is impacted by a leakage characteristic.

In block 1320, a transition delay time is determined, wherein the transition delay time is impacted by a leakage characteristic.

In block 1330, characteristics of a device are analyzed based upon the transition delay time. It is appreciated that a variety of characteristics can be analyzed.

FIG. 14 is a flow chart of exemplary leakage inverter formation process 1400 in accordance with one embodiment of the present invention.

In block 1410, a pull-up component is fabricated. In one embodiment, the pull up component includes an on/off driven transistor. In one exemplary implementation, the pull up component includes a MOS transistor.

In block 1420, a pull-down component is fabricated. In one embodiment, the pull down component includes an on/off driven transistor. In one exemplary implementation, the pull down component includes a MOS transistor.

In block 1430, a leakage component that impacts a pull-up or pull-down transition is fabricated. In one embodiment, the leakage component includes a leakage transistor that is driven to the off state. In one exemplary implementation, the leakage transistor is orders of magnitude (e.g., 3 times, 10 times 12 times, etc.) larger than a pull up or pull down transistor fabricated in blocks 1410 or 1420. The leakage inverter can have leakage characteristics large or strong enough to overcome the leakage characteristics of at least one of the transistors fabricated in blocks 1410 or 1420. The leakage transistor can be multi-finger (e.g., a plurality of leakage transistors shorted together, etc.). In one exemplary implementation, a leakage component includes 10 finger of ½ micron each. The leakage transistor can be large enough to discharge the diffusion capacitance without overpowering a driven on pull up or pull down component of blocks 1410 or 1420.

Present systems and methods can facilitate examination and analysis of leakage characteristics. In one embodiment, the leakage current limited delay is so large it dominates the ring oscillator frequency, which can be digitally measured with a counter. In one embodiment, there is a 50% duty cycle output similar to a clock, with frequency and duty cycle both determined by a slow transition, which can be used to drive a counter. In one exemplary implementation, the present operation examination approaches facilitate utilization of relatively small ring oscillations with asymmetric delay devices that achieve proper polarities. The present approaches can also allow for operation examination components to be selectively turned on and off facilitating further conservation of power consumption. The present approaches facilitate more monitoring structures to be instantiated than conventional attempts and at a lower area cost. The present approaches also facilitate closer monitoring of process and operating parameters. Present leakage inversion systems and methods can facilitate confirmation of chip compliance with design specifications and detection of manufacturing process irregularities.

Portions of the detailed description are presented and discussed in terms of a method. Although steps and sequencing thereof are disclosed in figures herein describing the operations of this method, such steps and sequencing are exemplary. Embodiments are well suited to performing various other steps or variations of the steps recited in the flowchart of the figure herein, and in a sequence other than that depicted and described herein.

Some portions of the detailed description are presented in terms of procedures, steps, logic blocks, processing, and other symbolic representations of operations on data bits that can be performed within a computer memory. These descriptions and representations are the means used by those skilled in the data processing arts to most effectively convey the substance of their work to others skilled in the art. A procedure, computer-executed step, logic block, process, etc., is here, and generally, conceived to be a self-consistent sequence of steps or instructions leading to a desired result. The steps include physical manipulations of physical quantities. Usually, though not necessarily, these quantities take the form of electrical, magnetic, optical or quantum signals capable of being stored, transferred, combined, compared, and otherwise manipulated in a computer system. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout, discussions utilizing terms such as “processing”, “computing”, “calculating”, “determining”, “displaying”, “accessing,” “writing,” “including,” “storing,” “transmitting,” “traversing,” “associating,” “identifying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Some embodiments may be described in the general context of computer-executable instructions, such as program modules, executed by one or more computers or other devices. Generally, program modules include routines, programs, objects, components, data structures, etc., that perform particular tasks or implement particular abstract data types. Typically the functionality of the program modules may be combined or distributed as desired in various embodiments.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

What is claimed is:

1. A ring oscillator comprising:
at least one leakage inverter configured to transition a signal, wherein a leakage characteristic impacts a transition of the signal and wherein the at least one leakage inverter is coupled as part of a ring path; and
an output that outputs an indication of the impacts the leakage characteristic has on the transition of the signal.

2. The ring oscillator of claim 1 in which an output signal of the at least one leakage inverter has a rising transition delay and a falling transition delay that are asymmetric.

3. The ring oscillator of claim 1 in which an output signal of the at least one leakage inverter has a rising transition delay that is relatively fast and a falling transition delay that is relatively slow.

4. The ring oscillator of claim 1 in which an output signal of the at least one leakage inverter has a rising transition delay that is relatively slow and a falling transition delay that is relatively fast.

5. The ring oscillator of claim 1 in which the at least one leakage inverter includes a leakage component coupled in series between the pull up component and the pull down component, wherein leakage in the leakage component impacts at least one transition.

6. The ring oscillator of claim 1 wherein said output is coupled to an analysis component.

7. The ring oscillator of claim 1 further comprising a control component coupled to the ring path to control a state of the signal.

8. The ring oscillator of claim 1 in which the at least one leakage inverter is coupled in series to another leakage inverter in the ring path.

9. A leakage inverter comprising:
a pull up component configurable to perform a pull up operation to pull up a signal;
a pull down component configurable to perform a pull down operation to pull down the signal; and
a leakage component coupled in series between the pull up component and the pull down component, wherein leakage in the leakage component impacts at least one transition of the signal.

10. The leakage inverter of claim 9 wherein the leakage component includes a transistor in the off state that allows leakage current to flow.

11. The leakage inverter of claim 9 wherein a transition delay associated with the pull down operation is asymmetric with respect to transition delay associated with the pull up operation and asymmetry is associated with an effect of the leakage current on the at least one transition of the signal.

12. The leakage inverter of claim 11 wherein a transition delay associated with the pull down operation is relatively slow with respect to transition delay associated with the pull up operation.

13. The ring oscillator of claim 1 wherein the at least one leakage inverter includes an NMOS component.

14. The ring oscillator of claim 1 wherein the at least one leakage inverter includes a PMOS component.

15. A leakage current detection method comprising:
receiving an input signal corresponding to a first logical state;
configuring at least one transistor on/off state; and
forwarding an output signal corresponding to a second logical state, wherein a leakage current affects a transition delay from the receiving the input signal corresponding to a first logical state and forwarding the output signal corresponding to a second logical state.

16. The leakage current detection method of claim 15 further comprising:
examining the delay from said receiving to said outputting;
determining impacts on operations based upon results of the examining.

17. The leakage current detection method of claim 15 further comprising
receiving an input signal corresponding to the second logical state;
reconfiguring the at least one transistor on/off state; and
forwarding an output signal corresponding to the first logical state;
wherein there is a second transition delay from the receiving the input signal corresponding to a second logical state and forwarding the output signal corresponding to a first logical state.

18. The leakage current detection of claim 15 wherein the first transition delay and the second transition delay are asymmetric.

19. The leakage current detection of claim 15 wherein the first transition delay is relatively fast and the second transition delay is relatively slow.

20. The leakage current detection of claim 15 further comprising controlling the flow and state of the signal between the respective pull up and pull down transistion.
